(19) United States
(12) Patent Application Publication
(10) Pub. No.: US 2013/0329157 A1
(43) Pub. Date: Dec. 12, 2013

(54) LIQUID CRYSTAL DISPLAY AND MANUFACTURING METHOD THEREOF

(71) Applicant: HannStar Display Corp., New Taipei City (TW)

(72) Inventors: Jung-Fang Chang, Tainan City (TW); Ming-Chieh Chang, Hsinchu County (TW); Po-Hsiao Chen, Tainan City (TW)

(21) Appl. No.: 13/910,653

(22) Filed: Jun. 5, 2013

(30) Foreign Application Priority Data
Jun. 7, 2012 (CN) 201210185419.X

(51) Int. Cl. G02F 1/136; H01L 33/00

(52) U.S. Cl. CPC G02F 1/136; H01L 33/005
USPC 349/43; 438/46

(57) ABSTRACT

The present invention relates to a liquid crystal display and a manufacturing method thereof. The insulation layer of the liquid crystal display has: a first surface having a first opening; a second surface having a second opening; and a connecting structure having a via formed between the first and the second surfaces, wherein the via connects the first opening and the second opening, and the second opening is smaller than the first opening. The manufacturing method includes the steps of: providing a semiconductor layer having a surface with an area; forming a photoresist layer on the area; forming a protective layer on the semiconductor layer and the photoresist layer; and removing the photoresist layer through a lift-off process, so as to form a via penetrating the protective layer to expose the area of the semiconductor.

The application claims the benefit of PRC Patent Application No. 201210185419.X, filed on Jun. 7, 2012, in the State Intellectual Property Office of the People's Republic of China, the disclosures for which are incorporated by reference as fully set forth herein.

### FIELD OF THE INVENTION

The present invention relates to a liquid crystal display and a manufacturing method thereof. More particularly, it relates to a liquid crystal display with an insulation layer having vias formed by a lift-off process.

### BACKGROUND OF THE INVENTION

In the manufacturing process for liquid crystal displays, a skilled person in the art knows that moisture would damage the semiconductor material in the process and even make the property worse, namely the semiconductor material is sensitive to moisture, especially the oxide semiconductor material. Therefore, an insulation layer or protective layer is important for the element, such as switch elements, thin film transistors and so on, in a liquid crystal display in the manufacturing process, and the essential factor of affecting the effectiveness of the insulation layer or the protective layer is the insulation material. In recent years, the skilled person in the art has tried everything possible to improve the manufacturing process or to change the material for insulating the oxide semiconductor in the liquid crystal display from moisture or enhancing the yield of the manufacturing process. For example, as described in the essay issued by Sony in the Society for Information Display's (SID) Display Week 2010, an Aluminum Oxide (Al₂O₃) layer can be used as an insulation material to greatly enhance the reliability of the element in the liquid crystal display.

In general, the etching for the insulation layer or the protective layer in the manufacturing process is usually performed by a wet etching process or a dry etching process, and the structure after the etching process is described as follows. Please refer to FIG. 1, which shows a structural drawing of an insulation layer after a wet etching process. The structure 100 has an oxide semiconductor layer 101, an insulation layer (or a protective layer) 102, and a via 103 formed by the wet etching process, and due to the wet etching process, the via 103 is represented by the shape with a wide top edge and a narrow down edge. Please refer to FIG. 2, which shows a structural drawing of an insulation layer after a dry etching process. The structure 200 has an oxide semiconductor layer 201, an insulation layer (or a protective layer) 202, and a via 203 formed by the dry etching process, and due to the fry etching process, the via 203 is represented by the shape with the same width of a top edge and a down edge. However, since some of the insulation materials have dense structures, such as Al₂O₃, the etching rate will be too low during wet etching or dry etching, so as to cause etching problems.

Therefore, it would be useful to invent a forming method and device to circumvent all the above issues. In order to fulfill this need the inventors have proposed an invention “LIQUID CRYSTAL DISPLAY AND MANUFACTURING METHOD THEREOF.” The summary of the present invention is described as follows.

### SUMMARY OF THE INVENTION

It is therefore an object of the present invention to provide a liquid crystal display and a manufacturing method thereof for solving the prior problems that insulation materials with dense structures are hard to be etched or patterned.

According to the first aspect of the present invention, a liquid crystal display is provided and includes a substrate; a gate metal layer formed on the substrate; a gate insulation layer formed on the gate metal layer; a first layer formed on the gate insulation layer; an insulation layer formed on the first layer and having a first and a second vias, wherein each of the first and the second vias has a first and a second lateral walls, and a first extension line of the first lateral wall and a second extension line of the second lateral wall intersect above the first layer; and a source metal layer and a drain metal layer formed on the insulation layer and coupled to the first layer through the first and the second vias respectively.

According to the second aspect of the present invention, a manufacturing method for a liquid crystal display is provided and includes the steps of: providing a substrate; forming a gate metal layer on the substrate; forming a gate insulation layer on the gate metal layer; forming a first layer on the gate insulation layer, wherein the first layer has a surface with an area; forming a protrusion on the area; forming another insulation layer on the first layer and the protrusion; and removing the protrusion by a lift-off process, so as to form a via penetrating the another insulation layer to expose the area.

According to the third aspect of the present invention, a liquid crystal display is provided and includes an insulation layer having: a first surface having a first opening; a second surface having a second opening; and a connecting structure having a via formed between the first and the second surfaces, wherein the via connects the first opening and the second opening, and the second opening is smaller than the first opening.

According to the fourth aspect of the present invention, a manufacturing method for a liquid crystal display is provided and includes the steps of: providing a semiconductor layer having a surface with an area; forming a photoresist layer on the area; forming a protective layer on the semiconductor layer and the photoresist layer; and removing the photoresist layer by a lift-off process, so as to form a via penetrating the protective layer to expose the area of the semiconductor.

The foregoing and other features and advantages of the present invention will be more clearly understood through the following descriptions with reference to the drawings:

### BRIEF DESCRIPTION OF THE DRAWINGS

FIG. 1 is a structural drawing showing an insulation layer after a wet etching process.

FIG. 2 is a structural drawing showing an insulation layer after a dry etching process.

FIG. 3 is a flow chart schematically showing the first preferred manufacturing method for a liquid crystal display.

FIG. 4(a) is a schematic diagram showing the structure and the cross-section for a liquid crystal display corresponding to Step 301 of the first preferred embodiment.

FIG. 4(b) is a schematic diagram showing the structure and the cross-section for a liquid crystal display corresponding to Step 302 of the first preferred embodiment.

FIG. 4(c) is a schematic diagram showing the structure and the cross-section for a liquid crystal display corresponding to Step 303 of the first preferred embodiment.

FIGS. 4(d) and 4(e) are schematic diagrams showing the structure and the cross-section for a liquid crystal display corresponding to Step 304 of the first preferred embodiment.

FIG. 5 is a flow chart schematically showing the second preferred manufacturing method for a liquid crystal display.

FIG. 6(a) is a schematic diagram showing the structure and the cross-section for a liquid crystal display corresponding to Step 501 of the second preferred embodiment.

FIG. 6(b) is a schematic diagram showing the structure and the cross-section for a liquid crystal display corresponding to Step 502 of the second preferred embodiment.

FIG. 6(c) is a schematic diagram showing the structure and the cross-section for a liquid crystal display corresponding to Step 503 of the second preferred embodiment.

FIG. 6(d) is a schematic diagram showing the half-tone process for a liquid crystal display corresponding to Step 504 of the second preferred embodiment.

FIG. 6(e) is a schematic diagram showing the structure and the cross-sections for a liquid crystal display corresponding to Step 504 of the second preferred embodiment.

FIG. 6(f) is a schematic diagram showing the structure and the cross-section for a liquid crystal display corresponding to Step 505 of the second preferred embodiment.

FIG. 6(g) is a schematic diagram showing the structure and the cross-section for a liquid crystal display corresponding to Step 506 of the second preferred embodiment.

FIG. 6(h) is a schematic diagram showing the structure and the cross-section for a liquid crystal display corresponding to Step 507 of the second preferred embodiment.

FIG. 6(i) is a schematic diagram showing the structure and the cross-section for a liquid crystal display corresponding to Step 508 of the second preferred embodiment.

FIG. 6(j) is a schematic diagram showing the structure and the cross-section for a liquid crystal display corresponding to Step 509 of the second preferred embodiment.

FIG. 6(k) is a schematic diagram showing the structure and the cross-section for a liquid crystal display corresponding to Step 510 of the second preferred embodiment.

FIG. 7 is a schematic diagram showing the structure of the third preferred embodiment.

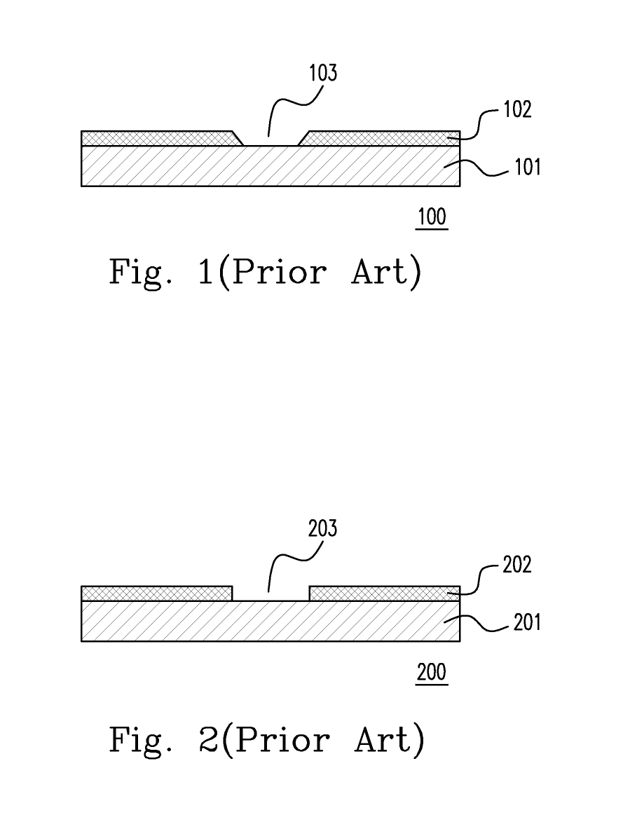

### DETAILED DESCRIPTION OF THE PREFERRED EMBODIMENT

The present invention will now be described more specifically with reference to the following embodiments. It is to be noted that the following descriptions of preferred embodiments of this invention are presented herein for the aspect of illustration and description only; it is not intended to be exhaustive or to be limited to the precise form disclosed.

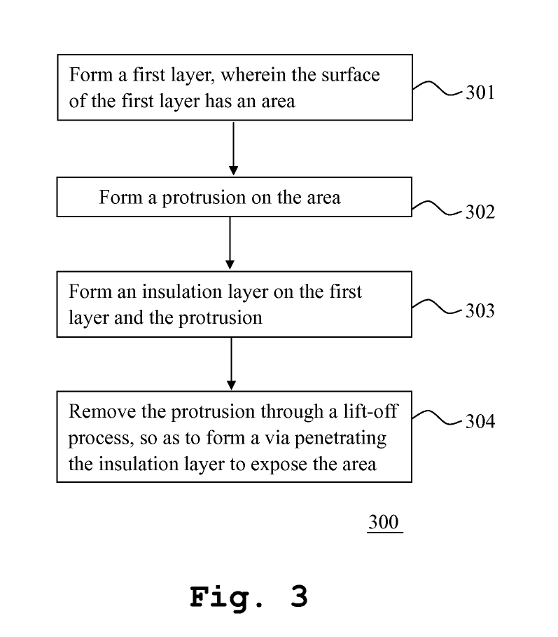

Please refer to FIG. 3, which is a flow chart schematically showing the first preferred manufacturing method for a liquid crystal display. The steps of the first preferred manufacturing method 300 are illustrated as follow.

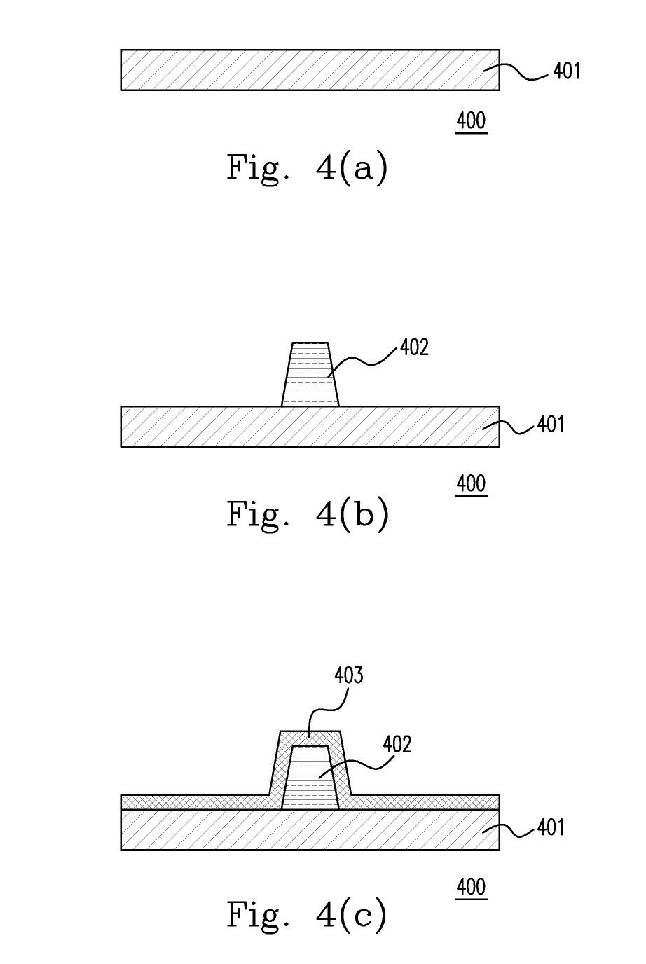

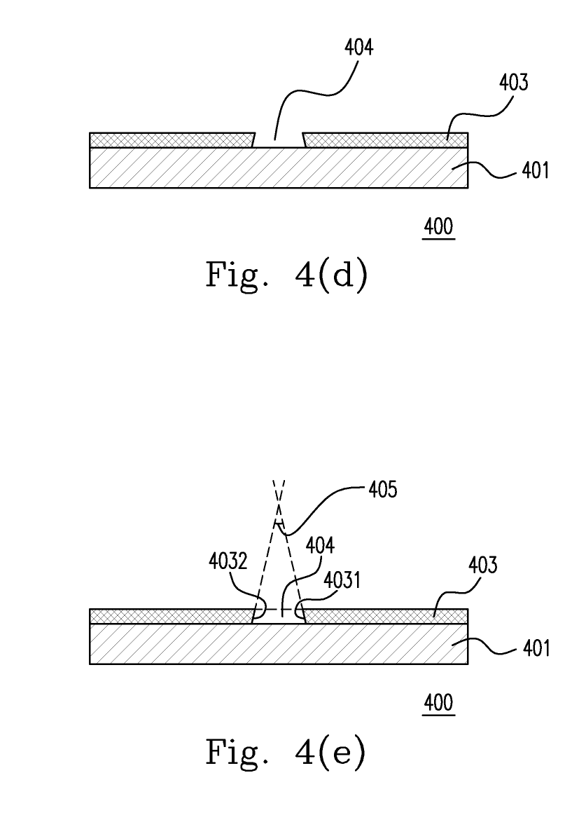

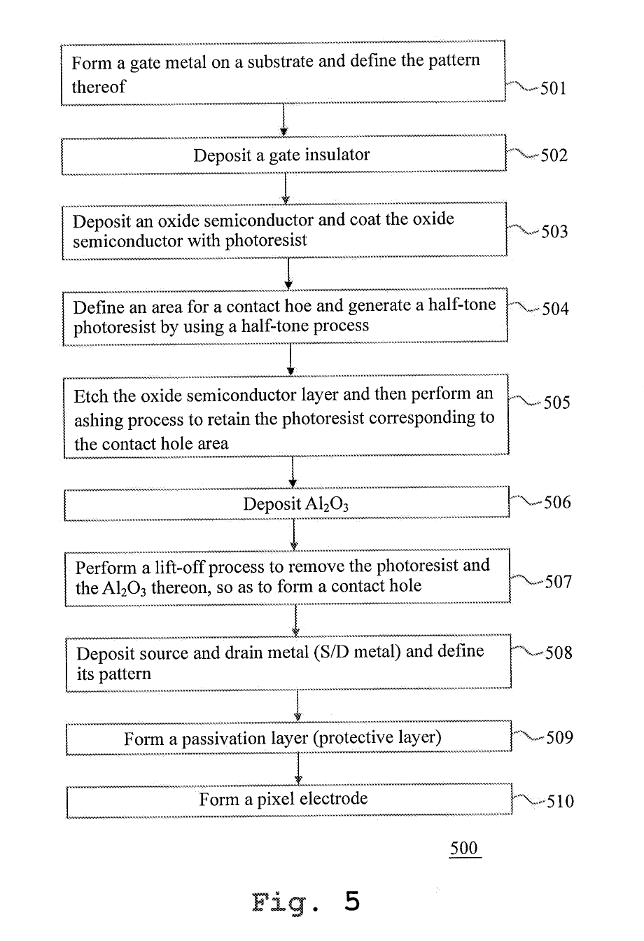

(Step 301) Form a first layer, wherein the surface of the first layer has an area. Please refer to FIG. 4(a), which is a schematic diagram showing the structure and the cross-section for a liquid crystal display corresponding to Step 301 of the first preferred embodiment. The structure 400 has a first layer 401, and the first layer preferably is a semiconductor layer, especially an oxide semiconductor, such as an Indium Gallium Zinc Oxide (IGZO) layer. The first layer also can be single phase or multi-phase oxide composition of Zn, Ga, In, Sn and so on.

(Step 302) Form a protrusion on the area. Please refer to FIG. 4(b), which is a schematic diagram showing the structure and the cross-section for a liquid crystal display corresponding to Step 302 of the first preferred embodiment. The structure 400 has a protrusion 402 formed on the area of the first layer 401, and the protrusion 402 is a cone, a pillar or a truncated pyramid, for example a quadrangular pyramid or a cone frustum. The protrusion 402 is made of photoresist or other conventional material. Furthermore, the step of forming the protrusion is performed by a half-tone process and an ashing process.

(Step 303) Form an insulation layer on the first layer and the protrusion. Please refer to FIG. 4(c), which is a schematic diagram showing the structure and the cross-section for a liquid crystal display corresponding to Step 303 of the first preferred embodiment. The structure 400 has an insulation layer 403, which covers the protrusion 402 and the first layer 401. The insulation layer 403 can function as a protective layer. The preferable insulation layer 403 is Al₂O₃, and can also be SiOₓ, SiNₓ, SiOₓNₓ or other insulation material.

(Step 304) Remove the protrusion through a lift-off process, so as to form a via penetrating the insulation layer to expose the area. Please refer to FIGS. 4(d) and 4(e), which are schematic diagrams showing the structure and the cross-section for a liquid crystal display corresponding to Step 304 of the first preferred embodiment. The insulation layer 403 in the structure 400 has a via (or a hole) 404, and the via 404 is formed by Step 304 and causes a part of the first layer 401 to be exposed. It is noted that from the cross-sections the via 404 displays a isosceles trapezoid with a narrow top edge and a wide down edge, and such a shape is naturally formed through the lift-off process. As to the top shape of the via 404 when viewed from above, it can be determined by the shape of the area of the first layer 401 covered by the protrusion 402, such as a rectangle, a circle and so on. In other words, the top shape of the via 404 can be determined by designing the protrusion 402. In addition, if the insulation layer is an Al₂O₃ layer, the thickness of the Al₂O₃ layer is preferably ranged between 5 Å and 500 Å, so as to facilitate the lift-off process. Furthermore, the via 404 is formed by the first layer 401 and the lateral edges 4031 and 4032 of the insulation layer 403, and the extension lines of the two lateral edges 4031 and 4032 intersect above the uncovered area of the first layer 401 and form a angle 405. The angle 405 is preferably ranged between 70° and 150°. From another point of view to defining the via 404, the via 404 can have incremental areas toward the uncovered area (i.e., in the downward direction from the intersection to the surface of the first layer 401). If the area perpendicular to the normal line to the surface of the first layer 401 is a rectangle, the via 404 has two pairs of the opposite lateral edges and the four lateral edges virtually intersect to a point above the first layer 401 and virtually form a pyramid. If the area perpendicular to the normal line to the surface of the first layer 401 is a circle, the via 404 has decremental areas from the bottom thereof (equal to the uncovered area of the first layer 401) to the top and these decremental areas virtually form a cone frustum.

Based on the above, the manufacturing step for the liquid crystal display provided by the present invention has the steps of: forming at least one protrusion first and then removing the protrusion and the insulation material thereon through the lift-off process, so as to form a via penetrating the insulation layer or the protective layer, and the via has areas incrementally increasing from the top to the bottom.

Please refer to FIG. 5, which is a flow chart schematically showing the second preferred manufacturing method for a liquid crystal display. The steps of the second preferred manufacturing method 500 are illustrated as follows:

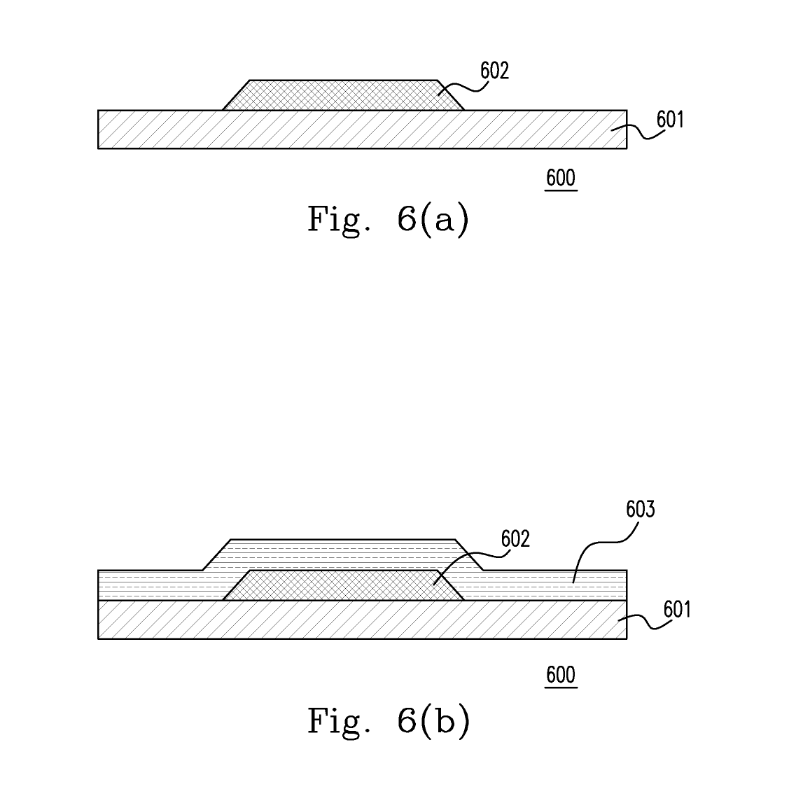

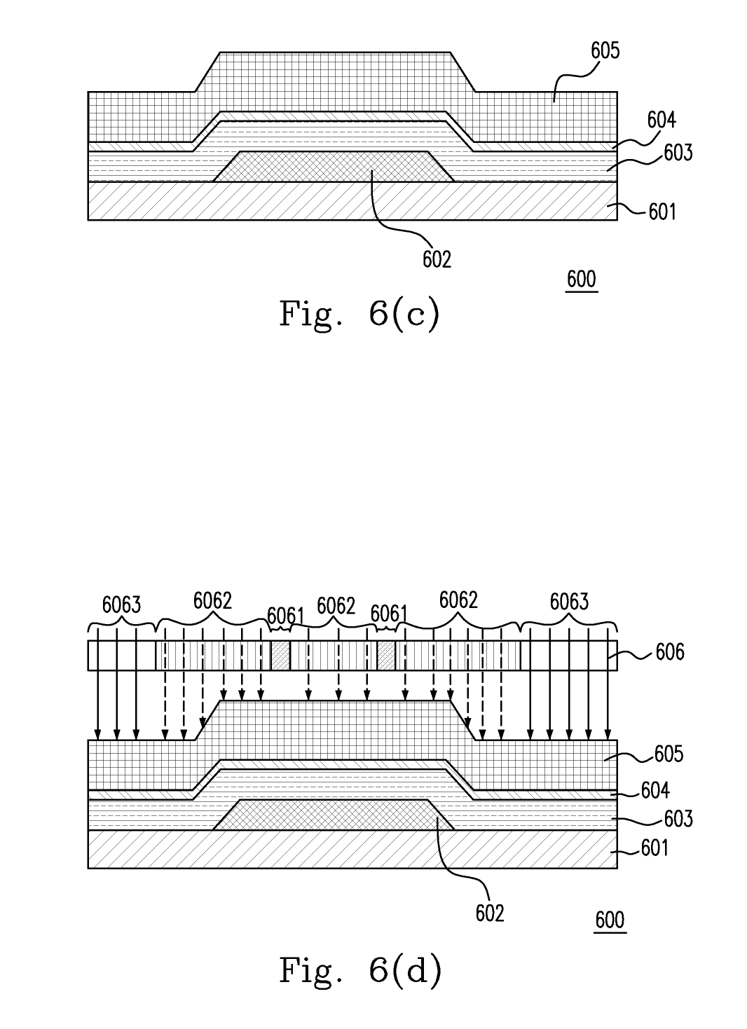

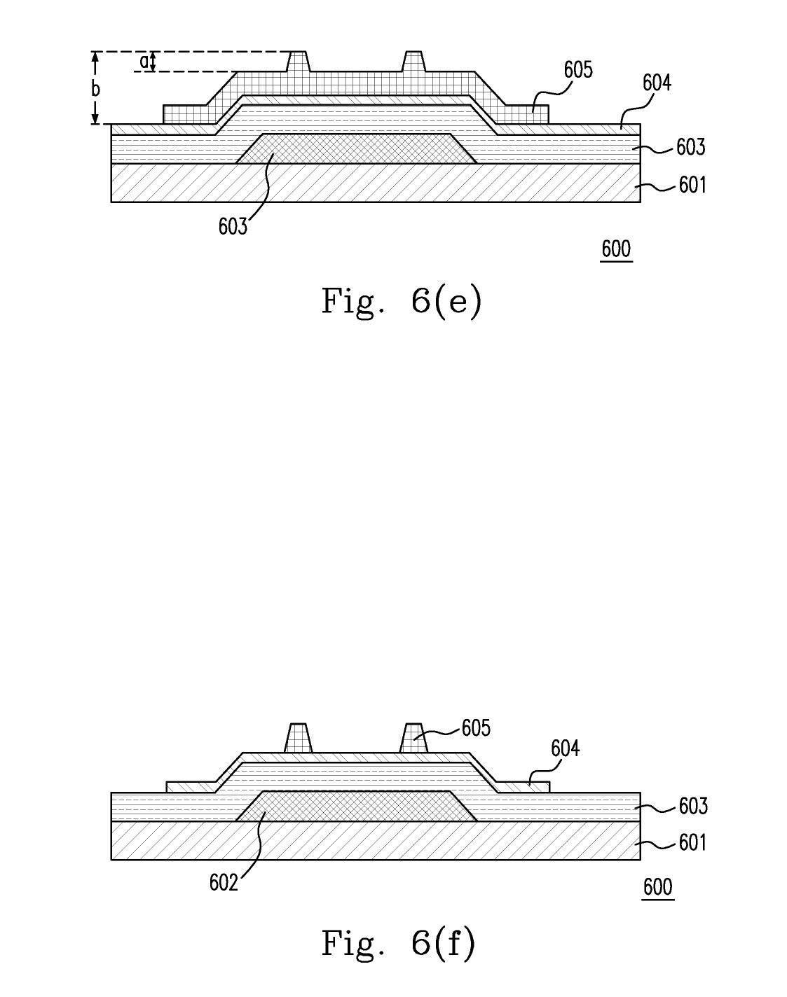

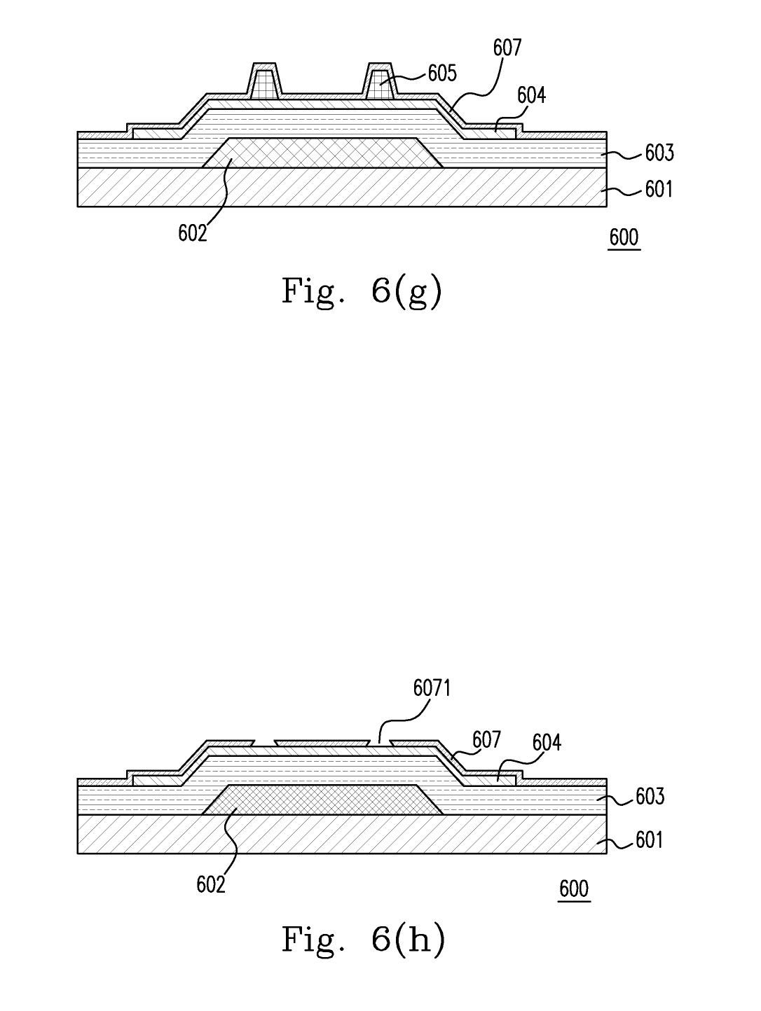

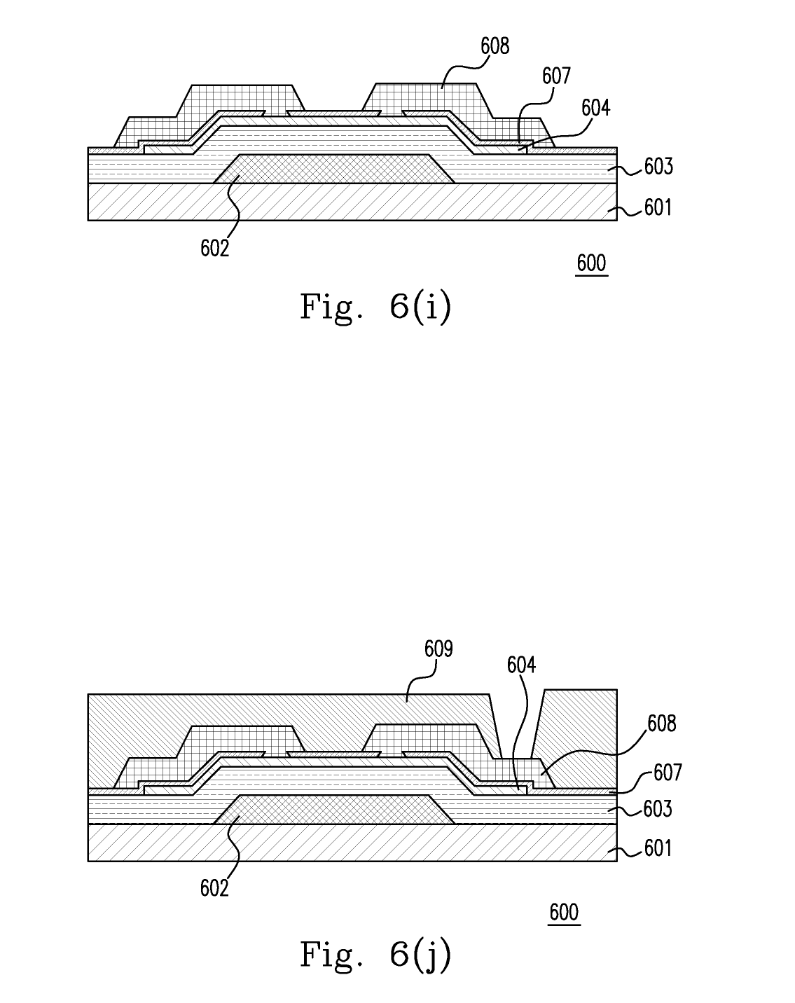

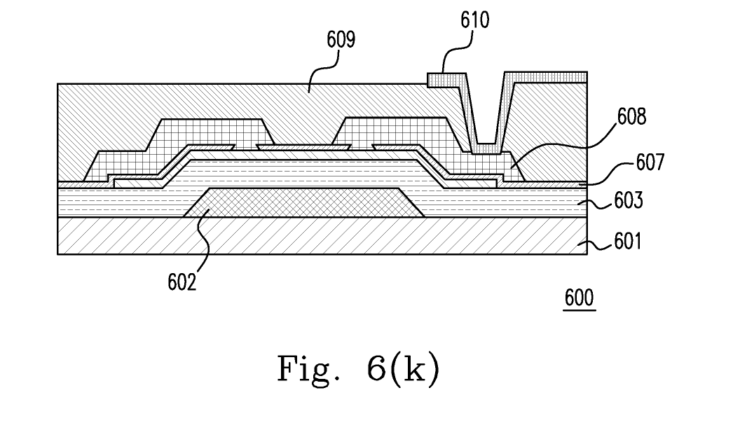

(Step 501) Form a gate metal on a substrate and define the pattern thereof. Please refer to FIG. 6(a), which is a schematic diagram showing the structure and the cross-section for a liquid crystal display corresponding to Step 501 of the second preferred embodiment. The structure 600 has a substrate 601 and a defined gate metal layer 602, and the defined gate metal layer 602 is disposed on the substrate 601.

(Step 502) Deposit a gate insulator. Please refer to FIG. 6(b), which is a schematic diagram showing the structure and the cross-section for a liquid crystal display corresponding to Step 502 of the second preferred embodiment. The structure 600 has an insulation layer 603, and the insulation layer 603 is disposed on the substrate 601 and the gate metal layer 602.

(Step 503) Deposit an oxide semiconductor and coat the oxide semiconductor with photoresist. Please refer to FIG. 6(c), which is a schematic diagram showing the structure and the cross-section for a liquid crystal display corresponding to Step 503 of the second preferred embodiment. The structure 600 has an oxide semiconductor layer 604 and a photoresist layer 605, and the oxide semiconductor layer 604 is disposed on the insulation layer 603 and the photoresist layer 605 is disposed on the oxide semiconductor layer 604. The oxide semiconductor layer 604 is preferably an Indium Gallium Zinc Oxide (IGZO) layer, but is not limited thereto. In another embodiment, the oxide semiconductor layer 604 can be another metal oxide semiconductor, such as a single-phase or multi-phase oxide composition of Zn, Ga, In, Sn and so on. In addition, the photoresist layer 605 has a thickness preferably ranging between 2 um and 4 um.

(Step 504) Define an area for a contact hoe and generate a half-tone photoresist by using a half-tone process, wherein the part corresponding to the contact hole of the half-tone photoresist has a thickness thicker than those of the others. Please refer to FIG. 6(d), which is a schematic diagram showing the half-tone process for a liquid crystal display corresponding to Step 504 of the second preferred embodiment. The half-tone photo mask 606 has three portions with their own transmittances different from one another for controlling the passage of light. In this case, the half-tone photo mask 606 has a first light-tight portion 6061 (substantially opaque), a second portion 6062 with a lower transmittance and a third portion 6063 with a higher transmittance. Furthermore, the half-tone photo mask is designed based on the contact hole area defined on the oxide semiconductor layer 604. When performing the exposure, the light will not pass the first portion 6061 because the first portion 6061 is opaque; only some of the light will pass the second portion 6062 (as shown by the dashed line) because the second portion 6062 has lower transmittance; and the light will almost pass the third portion 6063 (as shown by the solid line) because the third portion 6063 has higher transmittance. As a result of the different intensities of receiving the light for the photoresist layer 605, it causes the photoresist layer 605 to have three photoresist properties, so that the etching depths are different for the development. Please refer to FIG. 6(e), which is a schematic diagram showing the structure and the cross-sections for a liquid crystal display corresponding to Step 504 of the second preferred embodiment. The structure 600 has the exposed and developed photoresist layer 605, a so-called half-tone photoresist, and the exposed and developed photoresist layer 605 has two protrusions. The thickness “a” of the protrusion is preferably ranged between 1 um and 2 um, the thickness “b” of the unexposed and undeveloped photoresist layer 605 is preferably ranged between 2 um and 4 um, and in comparison to each other, there is a gap of 50%.

(Step 505) Etch the oxide semiconductor layer and then perform an ashing process to retain the photoresist corresponding to the contact hole area. Please refer to FIG. 6(f), which is a schematic diagram showing the structure and the cross-section for a liquid crystal display corresponding to Step 505 of the second preferred embodiment. The structure 600 has the etched oxide semiconductor layer 604 and the ashed photoresist layer 605. The ashed photoresist only includes two protrusions, and the area of the etched oxide semiconductor layer 604 contacted by the protrusions is the contact hole area defined by the step 504.

(Step 506) Deposit Al₂O₃. Please refer to FIG. 6(g), which is a schematic diagram showing the structure and the cross-section for a liquid crystal display corresponding to Step 506 of the second preferred embodiment. The structure 600 has an Al₂O₃ layer 607, which covers the insulation layer 603, the oxide semiconductor layer 604 and the photoresist layer 605. The deposition of Al₂O₃ can be performed by atomic layer deposition (ALD), physical vapor deposition (PVD) or other conventional process. Furthermore, the thickness of the Al₂O₃ layer 607 is preferably ranged between 5 Å and 500 Å. It is noted that the Al₂O₃ layer 607 functions as an insulation layer, so as to prevent the oxide semiconductor 604 from being exposed to moisture. In other embodiments, the Al₂O₃ layer 607 can be replaced with other insulation material, such as SiₓN_{y} or SiₓO_{y} with a low hydrogen content.

(Step 507) Perform a lift-off process to remove the photoresist and the Al₂O₃ thereon, so as to form a contact hole. Please refer to FIG. 6(h), which is a schematic diagram showing the structure and the cross-section for a liquid crystal display corresponding to Step 507 of the second preferred embodiment. The Al₂O₃ layer 607 of the structure 600 has a contact hole 6071, and the contact hole 6071 is formed by the lift-off process of Step 507. From the cross-section, the width of the top opening of the contact hole 6071 is smaller than that of the bottom opening thereof, and the area of the top opening perpendicular to the normal line to the substrate 601 is smaller than that of the bottom opening. The areas perpendicular to the normal line to the substrate 601 are preferably 2*2 um^{2˜4*4} um². Since the photoresist layer 605 and the Al₂O₃ thereof are removed by the lift-off process, the forming of the contact hole 6071 does not require an etching process, so the oxide semiconductor will not be damaged by etching. Therefore, the variant of the film thickness can be controlled within 5%.

(Step 508) Deposit source and drain metal (S/D metal) and define its pattern. Please refer to FIG. 6(i), which is a schematic diagram showing the structure and the cross-section for a liquid crystal display corresponding to Step 508 of the second preferred embodiment. The structure 600 has a patterned S/D metal layer 608, and the S/D metal layer 608 contacts the oxide semiconductor layer 604 via the contact hole 6071.

(Step 509) Form a passivation layer (protective layer). Please refer to FIG. 6(j), which is a schematic diagram showing the structure and the cross-section for a liquid crystal display corresponding to Step 509 of the second preferred embodiment. The structure 600 has a passivation layer 609, which covers the Al₂O₃ layer 607 and the S/D metal layer 608 and has a hole to expose a part of the S/D metal layer 608.

(Step 510) Form a pixel electrode. Please refer to FIG. 6(k), which is a schematic diagram showing the structure and the cross-section for a liquid crystal display corresponding to Step 510 of the second preferred embodiment. The structure 600 has a pixel electrode 610. The pixel electrode 610 is disposed on a part of the passivation layer 609 and contacts the exposed portion of the S/D metal layer 608, and the material used for the pixel electrode 610 is preferably an indium tin oxide (ITO).

The manufacturing process for a liquid crystal display provided by the present invention can be applied to semiconductor elements, especially switch elements and thin film transistors, for solving the prior deficiencies of the conventional manufacturing process.

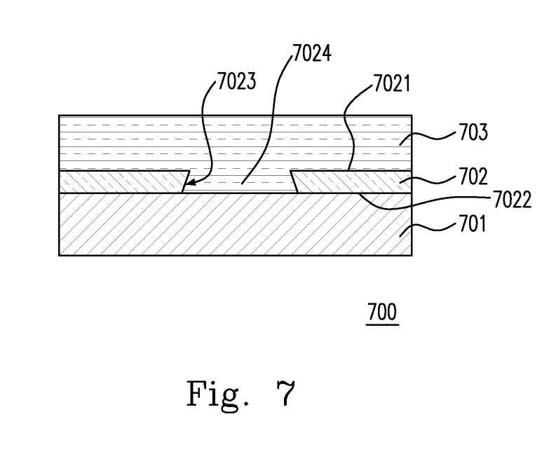

Please refer to FIG. 7, which is a schematic diagram showing the structure of the third preferred embodiment. The structure 700 has a semiconductor layer 701, an insulation layer 702 and a conductive layer 703, wherein the insulation layer 702 includes a first surface 7021, a second surface 7022 and a connecting structure 7023. The first surface 7021 contacts the conductive layer 7023, the second surface contacts the semiconductor layer 701, the connecting structure 7023 has a via 7024, the via 7024 is formed between the first surface 7021 and the second surface 7022, and the opening of the via 7024 at the second surface 7022 is larger than the opening at the first surface 7021. The semiconductor layer 701 contacts the conductive layer 703 via the connecting structure 7023, and that the bottom opening is larger than the top opening is caused by the lift-off process. It is noted that the extension lines of the two lateral sides of the connecting structure 7023 intersect at a point above the semiconductor layer 701, and this is also caused by the lift-off process.

There are still other embodiments, which are described as follows.

### Embodiment 1

A liquid crystal display includes a substrate; a gate metal layer formed on the substrate; a gate insulation layer formed on the gate metal layer; a first layer formed on the gate insulation layer; an insulation layer formed on the first layer and having a first and a second vias, wherein each of the first and the second vias has a first and a second lateral walls, and a first extension line of the first lateral wall and a second extension line of the second lateral wall intersect above the first layer; and a source metal layer and a drain metal layer formed on the insulation layer and coupled to the first layer through the first and the second vias respectively.

### Embodiment 2

According to the liquid crystal display of the above-mentioned embodiment 1, the first layer is an oxide semiconductor layer, and the insulation layer is an Aluminum Oxide (Al₂O₃) layer.

### Embodiment 3

According to the liquid crystal display of the above-mentioned embodiment 1 or 2, the oxide semiconductor layer is an Indium Gallium Zinc Oxide (IGZO) layer.

### Embodiment 4

According to the liquid crystal display of the above-mentioned embodiments 1˜3, the thickness of the Al₂O₃ layer ranges between 5 Å and 500 Å.

### Embodiment 5

According to the liquid crystal display of any one of the above-mentioned embodiments 1˜4, the angle formed by the first and the second extension lines ranges between 70° and 150°.

### Embodiment 6

A manufacturing method for a liquid crystal display includes the steps of: providing a substrate; forming a gate metal layer on the substrate; forming a gate insulation layer on the gate metal layer; forming a first layer on the gate insulation layer, wherein the first layer has a surface with an area; forming a protrusion on the area; forming another insulation layer on the first layer and the protrusion; and removing the protrusion by a lift-off process, so as to form a via penetrating the another insulation layer to expose the area.

### Embodiment 7

In the method according to any one of the above-mentioned embodiment 6, the protrusion forming step is performed by a half-tone process and an ashing process.

### Embodiment 8

In the method according to the above-mentioned embodiment 6 or 7, the first layer is an oxide semiconductor layer, the insulation layer is an Al₂O₃ layer, and the thickness of the Al₂O₃ layer ranges between 5 Å and 500 Å.

### Embodiment 9

A liquid crystal display includes an insulation layer having: a first surface with a first opening; a second surface with a second opening; and a connecting structure with a via formed between the first and the second surfaces, wherein the via connects the first opening and the second opening, and the second opening is smaller than the first opening.

### Embodiment 10

A liquid crystal display includes a first layer having a surface with an area; and an insulation layer formed on the first layer and having a via to expose the area, wherein there are incremental areas toward the area.

### Embodiment 11

According to the liquid crystal display of the above-mentioned embodiment 10, if the area of the via perpendicular to the normal line to the surface of the first layer is a rectangle, the via 404 has a pair of the opposite lateral surfaces and the two lateral surfaces virtually intersect above the first layer and form an angle being 70°˜150°.

### Embodiment 12

According to the liquid crystal display of the above-mentioned embodiment 10 or 11, if the area of the via perpendicular to the normal line to the surface of the first layer is a circle, the via has decremental areas from the bottom thereof to the top and these decremental areas virtually form a cone frustum with an angle being 70°˜150°.

### Embodiment 13

A manufacturing method for a liquid crystal display includes the steps of: providing a semiconductor layer having a surface with an area; forming a photoresist layer on the area; forming a protective layer on the semiconductor layer and the photoresist layer; and removing the photoresist layer by a lift-off process, so as to form a via penetrating the protective layer to expose the area of the semiconductor.

### Embodiment 14

In the method according to the above-mentioned embodiment 13, the semiconductor layer is an IGZO layer, the protective layer is an Al₂O₃ layer, and the photoresist layer is a half-tone photoresist layer.

### Embodiment 15

In the method according to the above-mentioned embodiment 13 or 14, the photoresist layer has a protrusion.

While the invention has been described in terms of what are presently considered to be the most practical and preferred embodiments, it is to be understood that the invention need not be limited to the disclosed embodiments. On the contrary, it is intended to cover various modifications and similar arrangements included within the spirit and scope of the appended claims, which are to be accorded with the broadest interpretation so as to encompass all such modifications and similar structures. Therefore the above description and illustration should not be taken as limiting the scope of the present invention which is defined by the appended claims.

What is claimed is:

1. A liquid crystal display, comprising:
a substrate;
a gate metal layer formed on the substrate;
a gate insulation layer formed on the gate metal layer;
a first layer formed on the gate insulation layer;
an insulation layer formed on the first layer and having a first and a second vias, wherein each of the first and the second vias has a first and a second lateral walls, and a first extension line of the first lateral wall and a second extension line of the second lateral wall intersect above the first layer; and
a source metal layer and a drain metal layer formed on the insulation layer and coupled to the first layer through the first and the second vias respectively.

2. The liquid crystal display as claimed in claim 1, wherein the first layer is an oxide semiconductor layer.

3. The liquid crystal display as claimed in claim 2, wherein the oxide semiconductor layer is an Indium Gallium Zinc Oxide (IGZO) layer.

4. The liquid crystal display as claimed in claim 1, wherein the insulation layer is an Aluminum Oxide (Al₂O₃) layer.

5. The liquid crystal display as claimed in claim 4, wherein the thickness of the Al₂O₃ layer is ranged between 5 Å and 500 Å.

6. The liquid crystal display as claimed in claim 1, wherein the angle formed by the first and the second extension lines is ranged between 70° and 150°.

7. A manufacturing method for a liquid crystal display, comprising the steps of:
providing a substrate;
forming a gate metal layer on the substrate;
forming a gate insulation layer on the gate metal layer;
forming a first layer on the gate insulation layer, wherein the first layer has a surface with an area;
forming a protrusion on the area;
forming another insulation layer on the first layer and the protrusion; and
removing the protrusion by a lift-off process, so as to form a via penetrating the another insulation layer to expose the area.

8. The manufacturing method as claimed in claim 7, wherein the protrusion forming step is performed by a half-tone process and an ashing process.

9. The manufacturing method as claimed in claim 7, wherein the first layer forming step further comprises a step of using an oxide semiconductor to form the first layer.

10. The manufacturing method as claimed in claim 7, wherein the another insulation layer forming step further comprises a step of using an Aluminum Oxide (Al₂O₃) to form the insulation layer.

11. The manufacturing method as claimed in claim 10, wherein the another insulation forming step further comprises a step of forming the insulation layer with an thickness ranged between 5 Å and 500 Å.

12. A liquid crystal display, comprising:
an insulation layer comprising:
a first surface having a first opening;
a second surface having a second opening; and
a connecting structure having a via formed between the first and the second surfaces, wherein the via connects the first opening and the second opening, and the second opening is smaller than the first opening.

13. The liquid crystal display as claimed in claim 12 further comprising a semiconductor layer contacting the first surface, and a conductive layer contacting the second surface, wherein the semiconductor layer contacts the conductive layer through the via.

14. The liquid crystal display as claimed in claim 13, wherein the semiconductor layer is an oxide semiconductor layer.

15. The liquid crystal display as claimed in claim 12, wherein the insulation layer is an Aluminum Oxide (Al₂O₃) layer.

16. The liquid crystal display as claimed in claim 15, wherein the Al₂O₃ layer has a thickness ranged between 5 Å and 500 Å.

17. A manufacturing method for a liquid crystal display, comprising the steps of:
providing a semiconductor layer having a surface with an area;
forming a photoresist layer on the area;
forming a protective layer on the semiconductor layer and the photoresist layer; and
removing the photoresist layer by a lift-off process, so as to form a via penetrating the protective layer to expose the area of the semiconductor.

18. The manufacturing method as claimed in claim 17, wherein the semiconductor layer providing step further comprises a step of using an Indium Gallium Zinc Oxide (IGZO) layer to form the semiconductor layer.

19. The manufacturing method as claimed in claim 17, wherein the protective layer forming step further comprises a step of using an Aluminum Oxide (Al₂O₃) to form the protective layer.

20. The manufacturing method as claimed in claim 17, wherein the photoresist layer is a half-tone photoresist layer.
